(19) United States
(12) Patent Application Publication
(10) Pub. No.: US 2014/0083971 A1
(43) Pub. Date: Mar. 27, 2014

(54) ETCHING SOLUTION, METHOD FOR MANUFACTURING PIEZOELECTRIC ELEMENT AND ETCHING METHOD

(71) Applicant: FUJIFILM CORPORATION, Tokyo (JP)

(72) Inventors: Takamichi FUJII, Kanagawa (JP); Akihiro MUKAIYAMA, Kanagawa (JP)

(73) Assignee: FUJIFILM CORPORATION, Tokyo (JP)

(21) Appl. No.: 14/030,985

(22) Filed: Sep. 18, 2013

(30) Foreign Application Priority Data
Sep. 25, 2012 (JP) 2012-210961

(51) Int. Cl. H01L 41/332

(52) U.S. Cl. CPC H01L 41/332
USPC 216/13; 252/79.3

(57) ABSTRACT

The present invention provides an etching solution for etching a piezoelectric film having a thin film of a perovskite structure grown to be a columnar structure on a lower electrode formed on a substrate and having a pyrochlore layer at an interface thereof with the lower electrode, wherein the etching solution comprises at least: a hydrofluoric acid type chemical comprising at least any of buffered hydrofluoric acid (BHF), hydrogen fluoride (HF), and diluted hydrofluoric acid (DHF); and nitric acid, and has a concentration by weight of hydrochloric acid of less than 10% and a weight ratio of hydrochloric acid to nitric acid (hydrochloric acid/nitric acid) of 1/4 or less. The present invention also provides a method of manufacturing a piezoelectric element to carry out etching using the etching solution.

### BACKGROUND OF THE INVENTION

1. Field of the Invention

The present invention relates to an etching solution, a method for manufacturing a piezoelectric element, and an etching method, specifically to an etching solution used for etching a piezoelectric film that is formed by non-epitaxial growth, a method for manufacturing a piezoelectric element, and an etching method.

2. Description of the Related Art

A piezoelectric element using a piezoelectric substance having piezoelectricity which stretches with changes in an applied electric field strength has been used as an actuator to be installed in an inkjet recording head, a sensor, or a memory element or the like. A wet etching process using an etching solution has been used as a method for forming a pattern on a piezoelectric substance.

Japanese Patent No. 4665025 describes, for example, an etching method using: one of hydrochloric acid and nitric acid; and one of fluorine compounds such as ammonium fluoride and hydrogen fluoride as a method for processing an epitaxially grown PZT film.

Japanese Patent No. 3201251 describes a two-step patterning, in which an etching is carried out with an etching solution composed of hydrofluoric acid, and sulfuric acid or hydrochloric acid followed by removing residual parts with a post-processing liquid composed of an acid in patterning a dielectric substance. In addition, the selectivity to a photoresist can be improved by carrying out etching in two steps.

Moreover, Japanese Patent Application Laid-Open No. 2004-31521 describes patterning that is carried out with a wet etching solution that contains one of hydrogen fluoride (HF), buffered hydrofluoric acid (BHF), diluted hydrofluoric acid (DHF), sulfuric acid (H₂SO₄), hydrochloric acid (HCl), and nitric acid (HNO₃).

### SUMMARY OF THE INVENTION

An etching method as described in Japanese Patent No. 4665025, however, had a problem that a noble metal electrode was formed on a Si substrate and the residues were left in etching a nonepitaxial PZT film and an Nb doped non-epitaxial PZT film. Moreover, there was a problem in Japanese Patent No. 3201251 that since etching was carried out in two steps, the process became complicated. There was also a problem in Japanese Patent Application Laid-Open No. 2004-31521 that residues were left unless a composition of an etching solution and a combination of a piezoelectric structure were optimized.

The present invention has been made in view of such circumstances, and an object of the present invention is to provide an etching solution, a method for manufacturing a piezoelectric element, and an etching method that are capable of removing residues after etching and obtaining an favorable pattern even in etching a piezoelectric film with a pyrochlore layer formed at an interface thereof with a lower electrode.

In order to achieve the object, the present invention provides an etching solution for etching a piezoelectric film having a thin film of a perovskite structure grown to be a columnar structure on a lower electrode formed on a substrate and a pyrochlore layer at an interface thereof with the lower electrode, the etching solution comprising at least: a hydrofluoric acid type chemical comprising at least any of buffered hydrofluoric acid (BHF), hydrogen fluoride (HF), and diluted hydrofluoric acid (DHF); and nitric acid, and wherein a concentration by weight of hydrochloric acid is less than 10%, and a weight ratio of hydrochloric acid to nitric acid (hydrochloric acid/nitric acid) is 1/4 or less.

According to the present invention, etching a piezoelectric film can be carried out by incorporating a hydrofluoric acid type chemical, nitric acid, and hydrochloric acid in an etching solution for etching a piezoelectric film. Further, the generation of chlorides in etching a piezoelectric film can be suppressed by setting a concentration of hydrochloric acid at less than 10% in the etching solution, and, at the same time, the chlorides can be removed by incorporating nitric acid in the etching solution. Furthermore, setting a weight ratio of hydrochloric acid to nitric acid in the above described range in the etching solution allows a removing rate by nitric acid in etching to increase due to the generation of chlorides, therefore etching can be carried out with no residues left.

By using the etching solution, etching can favorably be carried out. Therefore, etching of a piezoelectric film including a pyrochlore layer, in which residues were left by a conventional method, can favorably be carried out.

For an etching solution according to another aspect of the present invention, the surface roughness of a lower electrode Ra is preferably 2 nm or less.

According to another aspect of the present invention, the etching solution never penetrates into a lower electrode to damage a lower electrode or a substrate because a dense film is formed by setting the surface roughness of a lower electrode at 2 nm or less. Therefore etching can favorably be carried out.

For an etching solution according to another aspect of the present invention, the thickness of a pyrochlore layer is preferably 5 nm or more.

With an etching solution according to another aspect of the present invention, etching can be effectively carried out even for a piezoelectric film with a pyrochlore layer having a thickness of 5 nm or more.

An etching solution according to another aspect of the present invention preferably contains acetic acid.

With an etching solution according to another aspect of the present invention, the etching rate can be adjusted by incorporating acetic acid into the etching solution. An etching rate can be decreased by increasing the amount of acetic acid, and an etching rate can be increased by decreasing the amount of acetic acid.

An etching solution according to another aspect of the present invention preferably contains sulfuric acid.

With an etching solution according to another aspect of the present invention, etching performance can be improved by incorporating sulfuric acid into the etching solution.

For an etching solution according to another aspect of the present invention, the lower electrode is preferably a platinum group metal (ruthenium, rhodium, palladium, osmium, iridium, or platinum) or a metal oxide thereof.

With an etching solution according to another aspect of the present invention, sufficient piezoelectric performance can be obtained by using a platinum group metal as the lower electrode.

For an etching solution according to another aspect of the present invention, the lower electrode is preferably iridium or an iridium oxide.

With an etching solution according to another aspect of the present invention, the damage to a substrate can be reduced by using Ir as the lower electrode because the surface smoothness thereof becomes high and a dense film is formed thereon. Therefore etching can favorably be carried out.

For an etching solution according to another aspect of the present invention, the piezoelectric film preferably comprises Pb.

With an etching solution according to another aspect of the present invention, piezoelectric performance can be improved with a piezoelectric film comprising Pb.

For an etching solution according to another aspect of the present invention, the piezoelectric film preferably comprises Pb and 3 at % or more and 30 at % or less of Nb.

With an etching solution according to another aspect of the present invention, piezoelectric performance can be improved with a piezoelectric film comprising Nb. Moreover, a pyrochlore layer is easy to be formed at the interface with a lower electrode because the piezoelectric film contains Nb, however, even in such a case, etching can favorably be carried out.

For an etching solution according to another aspect of the present invention, the piezoelectric film is preferably formed by a vapor growth method.

In the case of a piezoelectric film that is a non-epitaxial film formed by a vapor growth method, a layer that is difficult to be etched is formed in an initial growth layer of the film because a pyrochlore layer is formed at the interface between the piezoelectric film and a lower electrode. With an etching solution according to the present invention, etching can be favorably carried out even for a piezoelectric film with a pyrochlore layer that is difficult to be etched present. In this aspect, a sputtering method may be used as a vapor growth method.

In order to achieve the above objects, the present invention provides a method for manufacturing a piezoelectric element comprising: a lower electrode forming step of forming a lower electrode on a substrate; a piezoelectric film forming step of forming a piezoelectric film on the lower electrode by a vapor growth method; an etching step of etching the piezoelectric film with the etching solution described above; and an upper electrode forming step of forming an upper electrode on the piezoelectric film after the etching step.

According to the present invention, the method comprises a step of etching a piezoelectric film with the etching solution described above, thus making it possible to favorably carry out etching of a piezoelectric film and to manufacture a piezoelectric element excellent in piezoelectric performance.

In order to achieve the above objects, the present invention provides an etching method for etching a piezoelectric film formed on an electrode having a surface roughness Ra of 2 nm or less on a substrate and having a pyrochlore layer at an interface thereof with the electrode, wherein the etching solution comprises at least: a hydrofluoric acid type chemical comprising at least: a hydrofluoric type acid comprising at least any of buffered hydrofluoric acid (BHF), hydrogen fluoride (HF), and diluted hydrofluoric acid (DHF); and nitric acid, and the etching solution has a concentration by weight of hydrochloric acid of less than 10% and a weight ratio of hydrochloric acid to nitric acid (hydrochloric acid/nitric acid) of 1/4 or less.

According to the present invention, etching of a piezoelectric film can favorably be carried out. In addition, although not described herein as other embodiment, the present invention can be implemented as an etching solution, a lower electrode and a piezoelectric film of the embodiment similar to the etching solution described above.

According to an etching solution, a method for manufacturing a piezoelectric element, and an etching method of the present invention, a favorable pattern with no residues left after etching can be formed. Particularly, an etching solution, a method for manufacturing a piezoelectric element, and an etching method of the present invention can preferably be used for etching such a piezoelectric film with a pyrochlore layer present at an interface between a lower electrode and the piezoelectric film that could not be removed with a conventional etching solution.

### BRIEF DESCRIPTION OF THE DRAWINGS

FIGS. 1A, 1B, 1C, 1D, 1E, 1F and 1G are diagrams illustrating a manufacturing method of a piezoelectric element;

FIG. 2 is an enlarged view of the vicinity of the interface between the lower electrode as shown in FIG. 1C and a piezoelectric film;

FIGS. 3A and 3B are diagrams showing a photograph of the state after etching in Example 1 (a) and Comparative Example 1 (b);

FIG. 4 is a table showing the analysis results of residues on the lower electrode; and

FIG. 5 is a table showing the results of Examples.

### DETAILED DESCRIPTION OF THE PREFERRED EMBODIMENTS

Preferred embodiments of an etching solution and a method for manufacturing a piezoelectric element according to the present invention are explained below with reference to accompanying drawings.

### <Method for Manufacturing Piezoelectric Element>

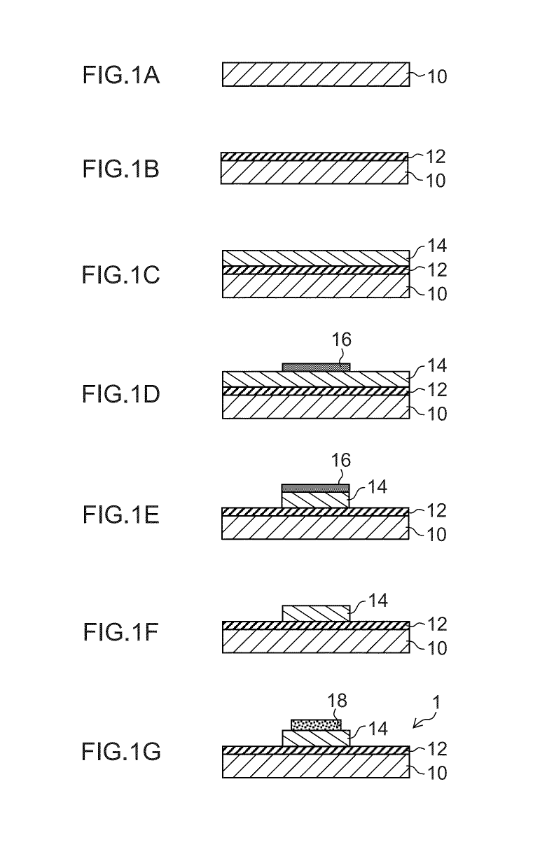

First, a method for manufacturing a piezoelectric element is explained. FIG. 1 shows an explanation drawing illustrating a manufacturing method of a piezoelectric element.

In the first place, a substrate 10 is prepared (FIG. 1A), and a lower electrode 12 is formed in a film state on the substrate 10 (FIG. 1B). Before a film forming of the lower electrode 12, a buffer layer or an adhesion layer may be formed in a film state. In the next place, a piezoelectric film 14 is formed on the lower electrode 12 (FIG. 1C), followed by patterning the piezoelectric film 14. The pattering of the piezoelectric film 14 is carried out by applying a resist 16 on the portion to be left in the piezoelectric film 14 (FIG. 1D) and removing the unnecessary portion by a wet etching (FIG. 1E). After that, the resist 16 is removed, an upper electrode 18 is formed in a film state on the patterned piezoelectric film 14, and a piezoelectric element 1 is obtained.

A film forming method for the piezoelectric film 14, the lower electrode 12, and the upper electrode 18 is not limited, and examples thereof include a vapor growth method using plasma such as a sputtering, an ion plating, a plasma CVD, a pulsed laser deposition (PLD) methods and an ion beam sputtering method.

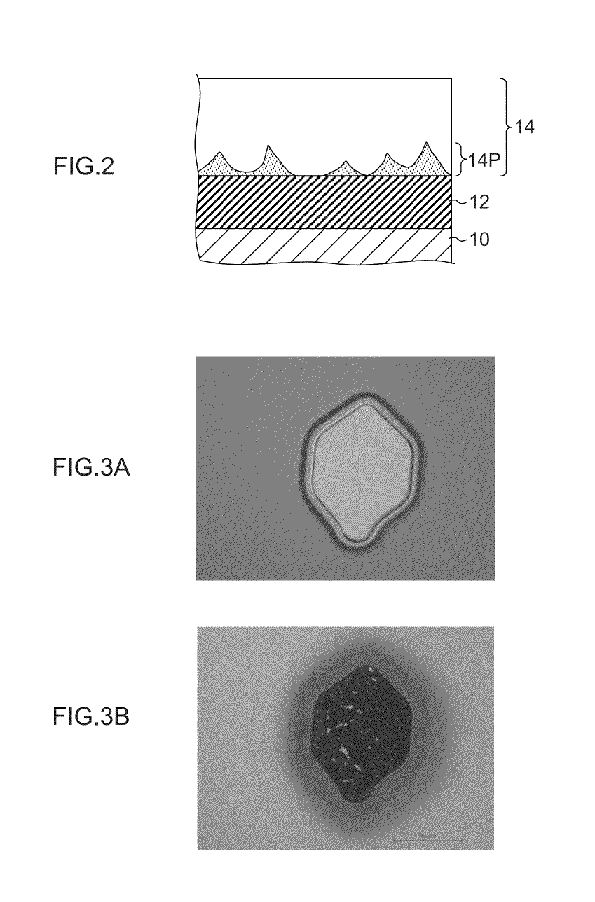

FIG. 2 shows an enlarged view of the vicinity of an interface between the lower electrode 12 as shown in FIG. 1C and the piezoelectric film 14. As shown in FIG. 2, a pyrochlore layer 14P composed of a pyrochlore oxide is formed at the interface of the piezoelectric film 14 with the lower electrode 12. Pyrochlore type oxides tend to be formed at the interface between the piezoelectric film 14 and the lower electrode 12 by the influence of a diffusion of oxygen or components constituting a piezoelectric film to an underlayer and so on. This pyrochlore layer 14P is difficult to be removed with an etching solution in patterning the piezoelectric film 14 and becomes a cause of residues on the lower electrode 12.

### <Constitution of Piezoelectric Element>

Next, a constitution of the piezoelectric element 1 is explained.

The substrate 10 is not specifically limited; however examples thereof include substrates such as silicon, glass, stainless (SUS), yttrium-stabilized zirconia (YSZ), SiTiO₃, alumina, sapphire, and silicon carbide. A laminated substrate such as an SOI substrate that a SiO₂ film and a Si active layer are sequentially laminated on a silicon substrate may be used as the substrate 10. Moreover, a buffer layer to make a lattice compatibility favorable, or an adhesion layer to make adhesion between an electrode and a substrate favorable or the like may be formed between the substrate 10 and the lower electrode 12.

A main component of the lower electrode 12 is not specifically limited; however examples thereof include a platinum group metal such as ruthenium (Ru), rhodium (Rh), palladium (Pd), osmium (Os), iridium (Ir), platinum (Pt) or a metal oxide thereof and combinations thereof. Using these materials as the lower electrode 12 allows piezoelectric performance to improve.

Among these components, iridium is preferably used as a main component of the lower electrode 12. Using iridium allows a surface roughness Ra of the lower electrode 12 to be smaller and to form a dense film. Thus, it is possible to prevent the etching solution from penetrating into the lower electrode 12 and damaging the substrate 10 in etching the piezoelectric film 14.

A main component of the upper electrode 18 is not specifically limited, however examples thereof include materials exemplified as the lower electrode 12, electrode materials generally used in a semiconductor process such as Al, Ta, Cr, and Cu, and combinations thereof.

A thickness of the lower electrode 12 and the upper electrode 18 are not specifically limited, but are preferably in the range from 50 to 500 nm.

A piezoelectric film 14 consists of one or more of a perovskite type oxide represented by the following general formula (P), where a B site element B preferably comprises Ti and Zr, and an A site element A preferably comprises at least one metal selected from the group consisting of Bi, Sr, Ba, Ca, and La.

General formula AₐB_{b}O₃ (P)

(wherein, A: an A site element; at least one element containing Pb as a main component, B: a B site element; at least one element selected from the group consisting of Ti, Zr, V, Nb, Ta, Cr, Mo, W, Mn, Sc, Co, Cu, In, Sn, Ga, Zn, Cd, Fe, and Ni; and O: oxygen. The case when a=1.0 and b=1.0 is standard, but these values may deviate from 1.0 as long as a perovskite structure can be maintained.)

Examples of a perovskite type oxide represented by the general formula (P) include lead titanate, lead zirconate titanate (PZT), lead zirconate, lead lanthanum titanate, lead lanthanum zirconate titanate, lead magnesium niobate-lead zirconium titanate, and lead nickel niobate-lead zirconium titanate. The piezoelectric film 14 may be a mixed crystal system of the perovskite type oxides represented by the general formula (P).

Particularly, incorporating Nb into a B site allows piezoelectric performance to improve. The content of Nb is preferably 3 at % or more and 30 at % or less. When the content of Nb is less than 3 at %, the effect of adding Nb cannot be obtained. Moreover, a pyrochlore layer that is a hetero layer without having piezoelectricity becomes easy to be formed by the addition of Nb. When the content of Nb exceeds 30 at %, a lot of pyrochlore layers are generated to unfavorably affect the piezoelectric performance.

As described above, although the pyrochlore layer becomes easy to be formed by incorporating Nb into a component of the piezoelectric film 14, etching with the etching solution described later makes it possible to etch the pyrochlore layer that was difficult to be etched with a conventional etching solution. Thus, an etching can favorably be carried out with no residues left.

Furthermore, the piezoelectric film 14 is preferably a columnar structured film composed of multiple columnar crystal substances extending toward a non-parallel direction to the substrate surface because a high piezoelectric performance can be obtained. As for the film structure composed of multiple columnar crystals extending toward a non-parallel direction to the substrate surface, an oriented film having an aligned crystal orientation can be obtained. Such a film structure can be obtained when a film is formed by a non-thermal equilibrium process such as a sputtering method. The growth direction of the columnar crystal may be substantially perpendicular or oblique to the substrate surface as long as it is a non-parallel direction to the substrate surface. The average diameter of multiple columnar crystals that constitute the piezoelectric film is not specifically limited, however a diameter of 30 nm or more and 1 μm or less is preferable.

The crystal structure of the piezoelectric film 14 is not specifically limited, however examples thereof include a tetragonal system, rhombohedral system, and a mixed crystal system thereof in a PZT system. In the case of Pb (Zr_{0.52}Ti_{0.48}) O₃ of MPB composition, for instance, a single crystal with a tetragonal structure, a mixed crystal with a tetragonal and rhombohedral structure, or a single crystal with a rhombohedral structure can be obtained depending on film forming conditions.

The film thickness of the piezoelectric film 14 is not specifically limited as long as an intended displacement magnitude is obtained, however a thickness of 500 nm or more is preferable, more preferably 2 to 5 μm.

Moreover, the pyrochlore layer 14P composed of a pyrochlore type oxide is formed at the interface of the piezoelectric film 14 with the lower electrode 12 as described above.

In general, a pyrochlore type oxide means a film represented by the general formula A₂B₂O₇. However, a pyrochlore type oxide that emerges as an impurity in a lead system piezoelectric substance includes A₃B₄O₁₃, A₅B₄O₁₅, and A₃B₂O₈ etc. in addition to A₂B₂O₇.

The pyrochlore layer cannot be removed and residues are left when a conventional etching solution is used. An excessive etching for the purpose of removing residues causes a resist to be stripped and causes a side etching to proceed, resulting in lowering a pattern accuracy.

In the embodiment of the present invention, a pyrochlore type oxide can effectively be removed by combining with the etching solution described later. Thus an etching can favorably be carried out with no residues left on the lower electrode.

Furthermore, a surface roughness Ra of the lower electrode 12 is preferably 2 nm or less. When a surface roughness Ra of the lower electrode 12 is more than 2 nm, the etching solution penetrates into the substrate (Si) 10 under the lower electrode 12, thereby giving damage to the substrate. By setting a surface roughness Ra of the lower electrode 12 in the range as described, the lower electrode 12 can be densely formed, therefore it becomes possible to prevent damage to the substrate 10 by the etching solution. Ir is preferably used as a material for the lower electrode 12 from a standpoint of making a surface smoothness of the lower electrode 12 high and forming a dense layer. It becomes possible to make a surface smoothness of the lower electrode 12 high and to form a dense film by using Ir. As for Pt, on the contrary, a surface of the lower electrode becomes easy to become rough and the etching solution becomes easy to penetrate between particles and to cause damage to the underlayer of Si.

### <Measurement of Average Film Thickness of Pyrochlore Layer>

An average film thickness of the pyrochlore layer was measured as follows.

1) By a high-angle annular dark-field (scanning transmission electron microscopy) (hereinafter, referred to as HAADF-STEM) method, a HAADF-STEM image of a cross section of the piezoelectric film perpendicular to the substrate surface (particularly, in an area of the piezoelectric substance to lower electrode interface) is captured. This image is defined as an original image.
2) By utilizing the fact that the contrasts in HAADF-STEM images are different between the perovskite type oxide layer and the pyrochlore type oxide layer, an image of the pyrochlore type oxide layer is binarized with a predetermined threshold value (for instance, when the original image has 256 gradations, the threshold value is about from 100 to 150.) by means of a contrast adjustment function of image processing software and is extracted by means of an edge extraction function thereof. The threshold value is determined in such a way that the noise is removed as much as possible and at the same time that what can clearly be distinguished as the pyrochlore type oxide layer can only be extracted. In the case when an outline of the pyrochlore type oxide layer is obscure in the binarized image, the outline thereof needs to be drawn empirically seeing the binarized image and the inner part of the obtained outline is filled.
3) An area of an extracted pyrochlore type oxide layer is calculated by the numbers of pixels of image processing software, and the calculated area is then divided by a width of a visual field in a HAADF-STEM image to be defined as an average film thickness.

A sample of which a HAADF-STEM image is to be captured in the paragraph 1) is processed in such a way that the sample has a uniform thickness of 100 nm in a depth direction (perpendicular to an observation direction). The reason why observation is done by a HAADF-STEM image is to remove the influence of a diffraction contrast and to observe the difference in the contrasts caused by the difference in density between the perovskite type oxide layer and the pyrochlore type oxide layer. Furthermore, in the measurement, an electron beam is made incident perpendicular to the substrate surface. As image processing software, Photoshop, for example, is used. In a binarized image, filling an area of the pyrochlore type oxide layer is to prevent an underestimation of the area.

Etching of the pyrochlore layer 14P having a film thickness of 5 nm or more thus measured can favorably be carried out with the etching solution described below. Furthermore, a thickness of the pyrochlore layer 14P is not specifically limited, and the pyrochlore layer can be removed with the etching solution according to the embodiment of the present invention by altering an etching condition and so on. However, a thickness of the pyrochlore layer 14P is preferably 10 nm or less. By setting a thickness of the pyrochlore layer 14P in the above described range, an etching can favorably be carried out.

### <Etching Solution>

An etching solution according to the embodiment of present invention is used for etching the piezoelectric film having the pyrochlore layer, and the etching solution comprises at least a hydrofluoric acid type chemical and nitric acid. Furthermore, hydrochloric acid may be used as long as a resist material has a hydrochloric acid resistance.

### (1) Fluorine Type Chemical

A hydrofluoric acid type chemical such as buffered hydrofluoric acid (BHF), ammonium fluoride (NH₄F), ammonium hydrogen fluoride (NH₄F.HF), hydrofluoric acid (HF), and diluted hydrofluoric acid (DHF) can favorably dissolve a material itself for a piezoelectric film such as PZT and respective metal oxides. A total concentration of a hydrofluoric acid type chemical is preferably 0.1% or more and 5% or less based on a total weight of the etching solution. It is a problem when the concentration is low because etching performance becomes deteriorated, and it is also a problem when the concentration is high because there occurs damage to a resist material.

### (2) Nitric Acid

Nitric acid is capable of etching while oxidizing a metal, therefore it becomes possible to improve an etching effect by mixing nitric acid with a fluorine type chemical. Particularly, nitric acid is capable of favorably etching a metal fluoride and so on (for example, lead fluoride) generated by a fluorine type etching solution.

In addition, nitric acid has an effect of etching lead fluoride and lead hydrochloride. Therefore, when an etching is carried out with a fluorine type chemical and the etching solution comprising hydrochloric acid described below, an etching can be carried out with nitric acid, although lead fluoride or lead chloride is generated.

A concentration of nitric acid is preferably 5% or more and 40% or less based on a total weight of the etching solution. When the concentration is low, less than 5%, residues are unfavorably left. When the concentration is high, a resist unfavorably receives damage resulting in an over etching.

### (3) Hydrochloric Acid

Hydrochloric acid is capable of etching while oxidizing a metal, therefore it becomes possible to improve an etching effect by mixing hydrochloric acid with a fluorine type chemical. Particularly, hydrochloric acid is capable of favorably etching a metal fluoride and so on (for example, lead fluoride) generated by a fluorine type etching solution. However, in the case of etching PZT with the etching solution comprising hydrochloric acid, hydrochloric acid leads to a reaction of Cl and Pb resulting in generating lead chloride which causes an etching not to proceed. Thus, as for the amount of hydrochloric acid, a smaller amount is more preferable.

The amount of HCl is preferably less than 10% based on a total weight of the etching solution, more preferably 5% or less. When the amount of HCl is 10% or more, a generation of chloride (lead chloride in the case of a PZT film) becomes dominant, thus an etching becomes difficult. It can be confirmed from an experiment that an etching can favorably be carried out by decreasing the amount of HCl to less than 10%. Etching performance that deteriorates as a result of decreasing the amount of hydrochloric acid can be compensated by increasing the amount of nitric acid.

### [Ratio of Hydrochloric Acid to Nitric Acid]

A ratio of hydrochloric acid to nitric acid (based on weight) expressed as hydrochloric acid/nitric acid is preferably 1/4 or less, more preferably 3/28 or less. It becomes possible to remove lead chloride generated as a result of a reaction of hydrochloric acid with PZT by adjusting the amount of nitric acid larger than that of hydrochloric acid, therefore etching can be carried out with no residues left.

### (4) Acetic Acid

Acetic acid has a similar effect as nitric acid and hydrochloric acid. Furthermore, acetic acid is capable of controlling an etching rate and facilitating an etching of residues by combining acetic acid with nitric acid. Although it has not been clearly understood, acetic acid has an effect of etching a pyrochlore layer favorably. When a large amount of acetic acid is added, effects of other liquid become weakened. Therefor it is preferable that acetic acid is added appropriately. A concentration of acetic acid is preferably 0% or more and 30% or less based on a total weight of the etching solution.

### (5) Sulfuric Acid

Sulfuric acid is used for etching a metallic material and etching a titanium oxide. As etching performance for a PZT film, an etching can favorably be carried out. However, since an excessive amount of sulfuric acid may dissolve a resist material, it is necessary to adjust the amount of addition.

The concentration of sulfuric acid is preferably 0% or more and 20% or less based on a total weight of the etching solution.

### (6) Water

Water can be used for adjusting the concentration of the chemicals described above.

### (7) Other Ingredients

The etching solution of the embodiment of the present invention may further be formulated with other ingredients, for example, a surfactant or a degradation preventing agent appropriately as needed within the range which does not interfere with the purpose of the present invention.

Hereinafter, the present invention is described in further detail with reference to Examples.

### Example 1

An adhesion layer of Ti (10 nm) was formed on a Si wafer, and an Ir layer having a thickness of 150 nm was formed thereon to make a lower electrode. After that, an Nb doped PZT film (3 μm) was formed. It could be confirmed from a TEM observation that a pyrochlore layer having a thickness of about 5 nm was present at an interface of the obtained film between the lower electrode and the PZT film. Moreover, the lower electrode had favorable surface characteristics with a surface roughness of about 1.5 nm when measured in an area of about 3 square microns with an atomic force microscope (AFM).

The obtained PZT film was patterned with a photoresist AZ5214E (manufactured by AZ Electronic materials S.A.).

After that, an etching process was carried out at room temperature with a mixture liquid consisting of 0.3% of ammonium hydrogen fluoride (NH₄F.HF), 1.2% of ammonium fluoride (NH₄F), 28% of nitric acid (HNO₃), 17% of acetic acid (CH₃COOH), and 53.5% of water. The etching process was carried out by immersing the object to be etched in a bath filled with the etching solution for 3 minutes and cleaning with flowing water sufficiently. Further, the etching process might be a dip method in which an object to be etched was immersed in a container filled with the etching solution or a spray method in which the etching solution was sprayed to the object to be etched.

Furthermore, an Nb doped PZT film was used as a PZT film, however a genuine PZT (a non-doped product) might also be used or a relaxer type material to which more types of materials were added might also be used. Still further, when a pyrochlore layer was present at an interface even in the case of a perovskite type non-lead piezoelectric film, the pyrochlore layer could be removed with the etching solution of the embodiment according to the present invention.

### Comparative Example 1

A sample preparation was done in the same way as in Example 1 until the completion of patterning a PZT film with a photoresist.

An etching was carried out by immersing the obtained film in an etching solution with a liquid mixture consisting of 0.3% of ammonium hydrogen fluoride, 1.2% of ammonium fluoride, 10% of hydrochloric acid, 0% of nitric acid, and 88.5% of water.

FIG. 3A shows a photograph of Example 1 after etching, and FIG. 3B shows a photograph of Comparative Example 1 after etching. In the figures, the central part shows the part removed by etching.

As shown in FIGS. 3A and 3B, it could be confirmed that the PZT film was etched; the lower electrode can be seen; and the etching was favorably carried out. In Comparative Example 1, residues were left at the interface.

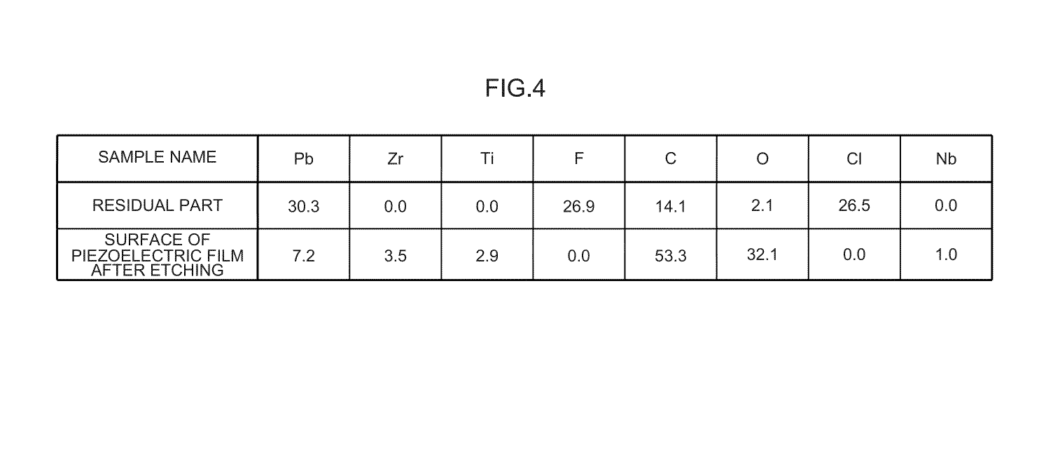

FIG. 4 shows the analysis results of residues. Further, the analyzed values of the surface of piezoelectric films after film formation are described as reference values. Pb, F, Cl, and trace amounts of O and C were left in the residues. It was inferred that lead chlorides and lead fluorides were left as residues.

### Reference Examples 1 to 3

Reference Examples 1 to 3 are the examples of etching a PZT film without a pyrochlore layer. Reference Example 1 is an example in which a conventional etching solution was used, Reference Examples 2 and 3 are examples in which the etching solution of the present invention was used. As shown in Reference Examples 1 to 3, it could be confirmed that an etching could favorably be carried out in the case of a piezoelectric film without having a pyrochlore layer with both the conventional etching solution and the etching solution of the present invention.

### Examples 2 to 4, 6

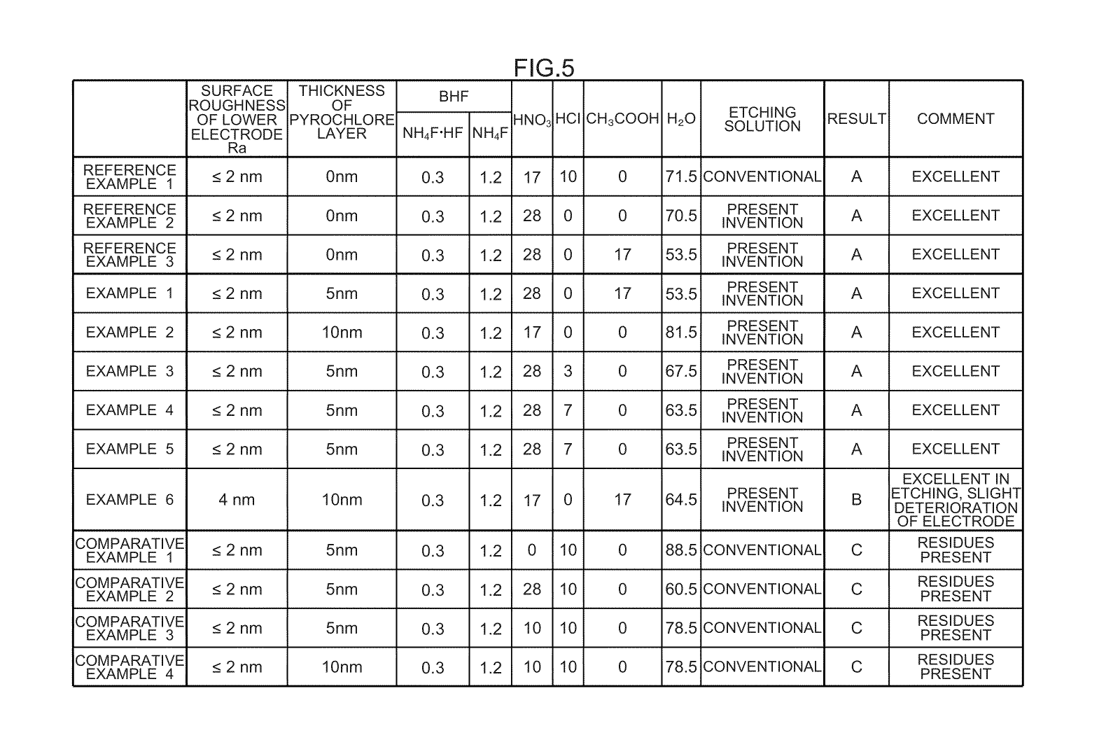

An etching was carried out in the same way as in Example 1 except that the composition of the etching solution was altered as shown in FIG. 5. In addition, the thickness of the pyrochlore layer of Example 2 was about 10 nm, the average surface roughness of the lower electrode of Example 6 was 4 nm, and the thickness of the pyrochlore layer was about 10 nm.

### Example 5

An etching was carried out in the same way as in Example 4 except that Pt was used as the lower electrode.

### Comparative Examples 2 to 4

An etching was carried out in the same way as in Comparative Example 1 except that the composition of the etching solution was altered. In addition, the thickness of the pyrochlore layer of Example 4 was about 10 nm.

### <Results>

Results were shown in FIG. 5. In addition, the results were evaluated by the following criteria.

A . . . an etching was favorably carried out with no residues left on the surface of a lower electrode.
B . . . an etching was favorably carried out with no residues left, but the deterioration of the lower electrode could be seen.
C . . . residues could be seen on the surface of the lower electrode.

As shown in FIG. 5, in the case of Examples 1 to 5 in which an etching process was carried out with the etching solution of the present invention, an etching was favorably carried out with no residues left even if a pyrochlore layer was formed at an interface with a lower electrode at the time of forming a piezoelectric film. In the case of Example 6, the PZT film could favorably be etched, but the etching solution penetrated into the lower electrode and the deterioration of the lower electrode could be seen slightly.

In the case of Comparative Examples 1 to 4 using the conventional etching solution, residues could be seen on the lower electrode.

What is claimed is:

1. An etching solution for etching a piezoelectric film having a thin film of a perovskite structure grown to be a columnar structure on a lower electrode formed on a substrate and a pyrochlore layer at an interface thereof with the lower electrode, the etching solution comprising at least:
a hydrofluoric acid type chemical comprising at least any of buffered hydrofluoric acid (BHF), hydrogen fluoride (HF), and diluted hydrofluoric acid (DHF); and
nitric acid, and
wherein a concentration by weight of hydrochloric acid is less than 10%, and a weight ratio of the hydrochloric acid to the nitric acid (hydrochloric acid/nitric acid) is 1/4 or less.

2. The etching solution according to claim 1, wherein the lower electrode has a surface roughness Ra of 2 nm or less.

3. The etching solution according to claim 1, wherein the pyrochlore layer has a thickness of 5 nm or more.

4. The etching solution according to claim 1, further comprising acetic acid.

5. The etching solution according to claim 1, further comprising sulfuric acid.

6. The etching solution according to claim 1, wherein the lower electrode is a platinum group metal (ruthenium, rhodium, palladium, osmium, iridium, or platinum) or a metal oxide thereof.

7. The etching solution according to claim 6, wherein the lower electrode is iridium or iridium oxide.

8. The etching solution according to claim 1, wherein the piezoelectric film comprises Pb.

9. The etching solution according to claim 1, wherein the piezoelectric film comprises Pb and 3 at % or more and 30 at % or less of Nb.

10. The etching solution according to claim 1, wherein the piezoelectric film is formed by a vapor growth method.

11. A method for manufacturing a piezoelectric element comprising:
a lower electrode forming step of forming a lower electrode on a substrate;
a piezoelectric film forming step of forming a piezoelectric film on the lower electrode by a vapor growth method;
an etching step of etching the piezoelectric film with the etching solution according to claim 1; and
an upper electrode forming step of forming an upper electrode on the piezoelectric film after the etching step.

12. An etching method for etching a piezoelectric film formed on an electrode having a surface roughness Ra of 2 nm or less on a substrate and having a pyrochlore layer at an interface thereof with the electrode, wherein the etching solution comprises at least a hydrofluoric acid type chemical comprising at least any of buffered hydrofluoric acid (BHF), hydrogen fluoride (HF), and diluted hydrofluoric acid (DHF); and nitric acid, and has a concentration by weight of hydrochloric acid of less than 10% and a weight ratio of the hydrochloric acid to the nitric acid (hydrochloric acid/nitric acid) of 1/4 or less.
